(19) United States
(12) Patent Application Publication
(10) Pub. No.: US 2007/0230136 A1
(43) Pub. Date: Oct. 4, 2007

(54) Heat sink fastening structure

(75) Inventor: Win-Haw Chen, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/391,905

(22) Filed: Mar. 28, 2006

(51) Int. Cl. H05K 7/20

(52) U.S. Cl. 361/719

(57) ABSTRACT

A heat sink fastening structure for fixing a heat sink on a semiconductor package of a circuit board, includes a fixture having disposing space for disposing the heat sink therein; two sliding members respectively formed on the two bottom-lateral sides of the fixture; and two linkage arrangements respectively mounted on the two lateral sides of the fixture and pivotally coupled with the sliding members, so as to facilitate the movement of the linkage arrangements to drive the sliding members for fixing the heat sink thereon.

### FIELD OF THE INVENTION

The present invention relates to heat sink fastening structures, and more particular, to a heat sink fastening structure which is simple in structure and allows easy operation and secure fastening of a heat sink on a fixture.

### BACKGROUND OF THE INVENTION

A Central Processor unit (CPU) is the central part of the operational unit of the computer, therefore plays a primary role in the operation of a computer. However, a CPU generates a significant amount of heat when it operates at high frequencies and speeds, and high temperature may cause a computer system crashing, therefore, in order to solve this problem, a heat dissipating device is provided in the package to dissipate heat generated by the CPU.

Referring to FIG. 1, a conventional heat dissipating device for dissipating heat from Central Processor Unit is disclosed by a Taiwan Patent No: 456586, comprising, a CPU holder 10, a heat sink 11 and a fastener 12. The Central Processor Unit 13 is mounted on the CPU holder 10 while the heat sink 11 is overlaid on the topside of a Central Processor Unit 13, which is fixed by a fastener 12 on the CPU holder 10. The fastener 12 has a retaining part 121 downwardly bended, of which both ends are respectively diagonally extended upwardly and bended downwardly forming a fastening part 122 thereof, a suspending hole 123 is formed thereof at the nearer end of a fastening part 122, which couples with a hook 101 on the lateral side of the CPU holder 10, so as to couple the heat sink 11, Central Processor Unit 13 and the CUP holder 10 together.

However, during the process of assembling and dissembling the fastener 12, particular tools are required to hook or unhook the suspending hole 123 of the fastener 12 on the hook 101 of the CPU holder 10, therefore it is extremely inconvenient to use.

Furthermore, due to the frequencies and speeds of the Central Processor Unit (CPU)13 is rapidly increasing along with the development of the micro-electronical industry; the amount of heat generated is relatively increasing. This leads to an increase in volumes and weights of the heat dissipating device in the CPU. Therefore, in order for the heat sink 11 to be closely positioned on the surface of the CPU using a fastener 12 to fasten the heat sink 11 on a CPU holder 10, the fastener 12 must be fastened to a CPU holder 10, which may easily result in an uneven force on both sides of the heat sink 11 thereby affecting fastening quality. Moreover, the process to install the fastener is complicated, so that it is inconvenient to use.

In the view of the prior art, apart from incontinence of assembling, it is also difficult to disassemble when a user wants to change a heat sink.

Therefore, there is an urgent need to improve the conventional fixing structure of a heat sink 11 mounted on a CUP holder 10, so that it is easily assembled and disassembled, allowing the heat sink 11 to be evenly attached on a Central Processor 13.

### SUMMARY OF THE INVENTION

In the view of the prior art drawbacks, a primary objective of the present invention is to provide a heat sink fastening structure which is simple in structure and easy to assemble.

Another objective of the present invention is to provide a heat sink fastening structure which is easy to disassemble.

Still another objective of the present invention is to provide a heat sink fastening structure, so that a heat sink is attached evenly on a Central Processor Unit.

In order to achieve the foregoing objectives, the present invention provides a heat sink fastening structure which fixes a heat sink on a semiconductor package of a circuit board, comprising: a fixture having disposing space for disposing the heat sink therein; whereon, two sliding members respectively formed on the two bottom-lateral sides of the fixture; and two linkage arrangements respectively mounted on the two lateral sides of the fixture; and the linkage arrangement pivotally coupled with the sliding member, so as to facilitate the linkage arrangement to drive the sliding member for fixing the heat sink thereon.

At least two opposing protruding columns are mounted on the bottom side of the heat sink. A through hole is respectively mounted on two lateral sides of the fixture and on a sliding member, whereon a long groove hole is respectively formed which is opposing the through hole of the fixture, and a elastic member is mounted diagonally thereon. A locking slot is mounted on the elastic member at the position opposing to the long groove hole of the sliding member. Moreover, The locking slot has a larger diameter on one end, and a smaller diameter on the other end, allowing the heat sink to be fixed into the disposing space of the fixture. The protruding column of the heat sink penetrates the through hole of the fixture, the long groove hole of the sliding member and the locking slot of the elastic member, facilitating movement of the linkage arrangement, so as to move the sliding member. At this time the protruding column of the heat sink moves from one end of larger diameter to the other end of the smaller diameter, thus, the heat sink is fastened on the fixture via the elasticity produced by the elastic member diagonally mounted thereon.

The linkage arrangement comprises a toggle mechanism pivotally coupled with a lift lever pivotally coupled with a sliding member, so as to permit the movement of the sliding member. The toggle mechanism comprises a lever, short lever, and swing lever coupled with the lift lever; the lever moves upwardly and downwardly to transmit the movement of the short lever, swing lever and then lift lever, so that the sliding member is transposed, allowing the protruding column of the heat sink to penetrate the locking slot of the elastic member and then move from one end of larger diameter to the other end of smaller diameter, so as to fasten the heat sink.

The heat sink fastening structure proposed by the present invention therefore permits easy assembly and dissembly, furthermore, the pressure on the heat sink is evenly distributed, allowing the heat sink to be attached more evenly on a semiconductor package, compared to the prior art, so as to achieve optimal efficiency during operation.

### BRIEF DESCRIPTION OF THE DRAWINGS

FIG. 1 (PRIOR ART) is a cross-sectional 3-D decomposition diagram of the Taiwan Patent No: 456586;

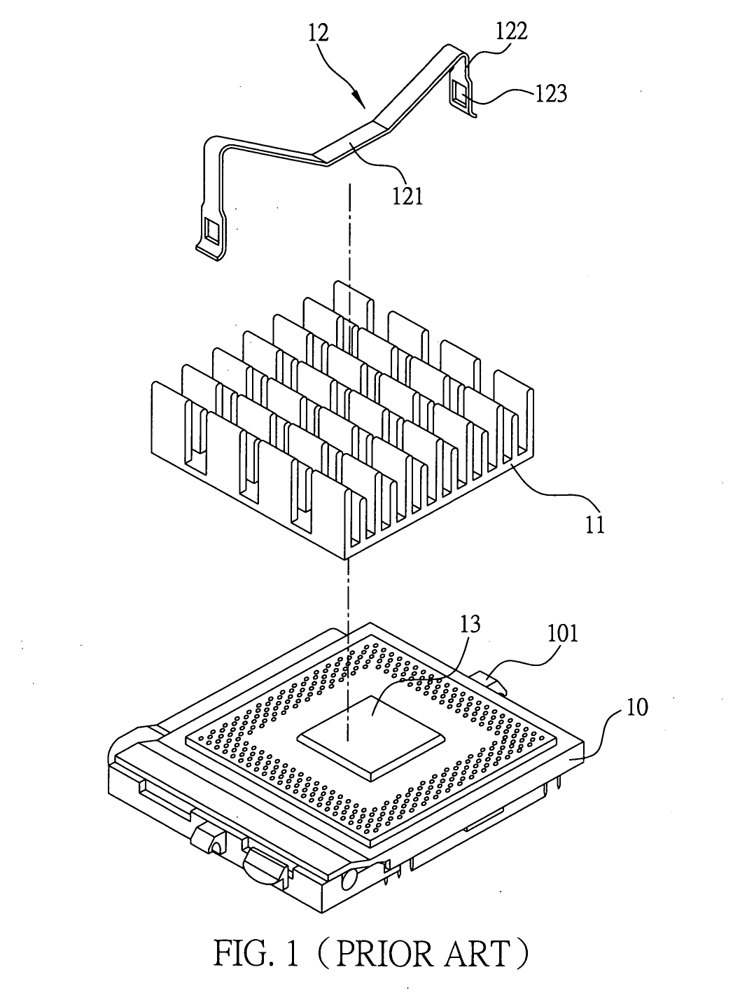

FIG. 2 is a cross-sectional 3-D decomposition diagram showing a heat sink fastening structure mounted on a circuit board of the present invention;

FIG. 3 is a cross-sectional view showing a heat sink fastening structure of the present invention;

FIG. 4 is a 3-D decomposition diagram showing a heat sink fastening structure partially in accordance with the invention; and

FIG. 5 is a 3-D decomposition diagram showing a partial linkage arrangement of a heat sink fastening structure.

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention. In addition, the drawing and the components shown herein are not to scale and are made in simplicity with provision of only associated components related to the invention; in practical usage, the component should be more complexly structured and the number, size, shape and arrangement of each component can be varied accordingly.

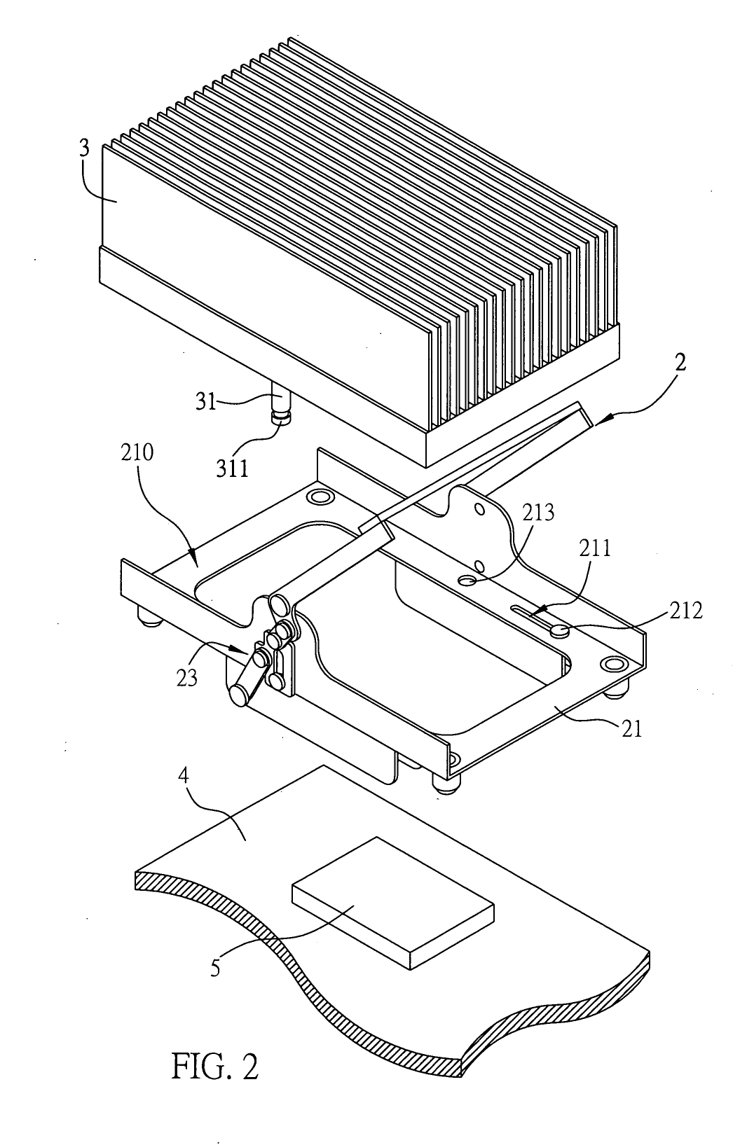

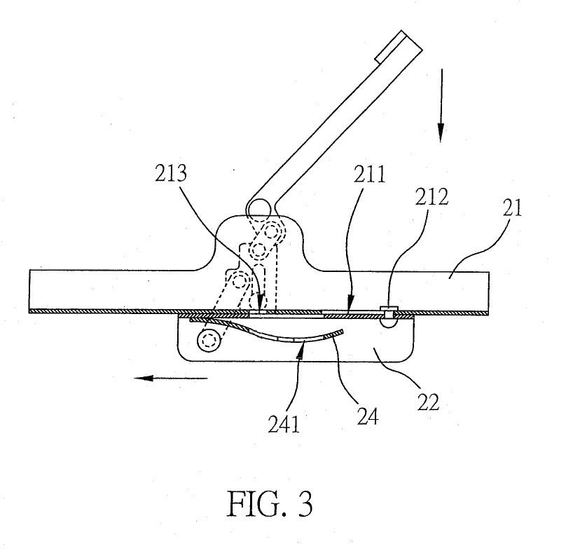

Referring to FIG. 2 and FIG. 3, a heat sink fastening structure 2 of the present invention for fixing a heat sink 3 on a semiconductor package 5 of a circuit board 4, comprises a fixture 21, two sliding members 22 and two linkage arrangements 23.

The fixture 21 has a disposing space 210 for disposing a heat sink 3 therein. Two long groove holes 211 are mounted respectively on the two lateral sides of the fixture 21, wherein a locating pin 212 is mounted. The locating pin 212 is coupled to a sliding member 22, in a way that the sliding member 22 slides underneath the fixture 21. Furthermore, the linkage arrangement 23 is mounted respectively on two lateral sides of the fixture 21 and the sliding member 22 is pivotally coupled with the sliding member 22, so that the sliding member is moved via the linkage arrangement, so as to fasten the heat sink 3.

A semiconductor package 5 can be for example a CPU, and the fixture 21 is placed on the outer surface of a semiconductor package 5 and coupled on the circuit board 4 allowing the heat sink 3 to be disposed in the disposing space 210 of the fixture 21, and attached to the semiconductor package 5, so as to make the linkage arrangement 23 to drive the sliding member 22, thereby fastening the heat sink 3 on the fixture 21. As a result, the heat sink 3 is securely attached on the semiconductor package 5.

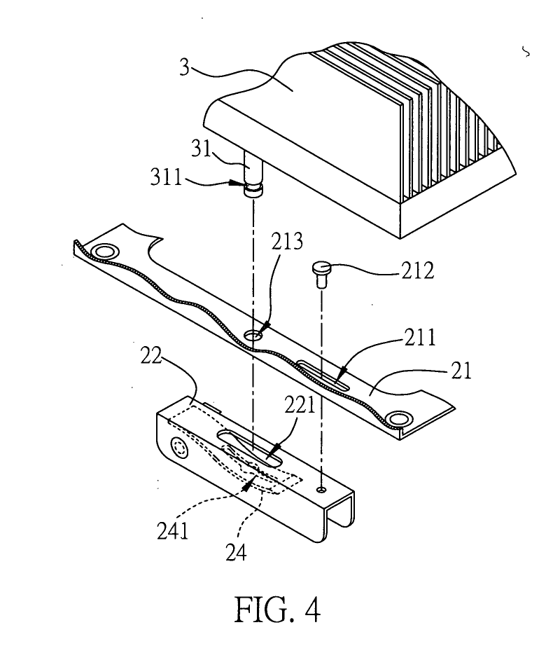

Referring to FIG. 4, a least two opposing protruding columns 31 having a slot 311 surrounding on the outside surface thereof are mounted on the bottom side of the heat sink 3. A through hole 213 is respectively formed on two lateral sides of the fixture 21 and the sliding member 22, while a long groove hole 221 is formed on the sliding member 22 at the position opposing the through hole 213 of the fixture 21. An elastic member 24 is mounted diagonally on the sliding member 22. A locking slot 241 is mounted on the elastic member 24 at the position opposing to the long groove hole 221 of the sliding member 22, so as to insert the protruding column 31 of the heat sink 3 through the through hole 213 of the fixture, long groove hole 221 of the sliding member 22 and the locking slot 241 of the elastic member 24. Since the diameter of one end of the locking slot 241 is larger than the other end, when the linkage arrangement 23 is pushed, the sliding member 22 is moved from one end of the locking slot 241 with a larger diameter, to the other end of the locking slot 241 with a smaller diameter so as to allow the protruding column 31 to be inserted into the locking slot 241 via the elastic force provided by the elastic member 24 diagonally mounted thereon to drive the protruding column 31, thereby fastening the heat sink 3 on the fixture 21.

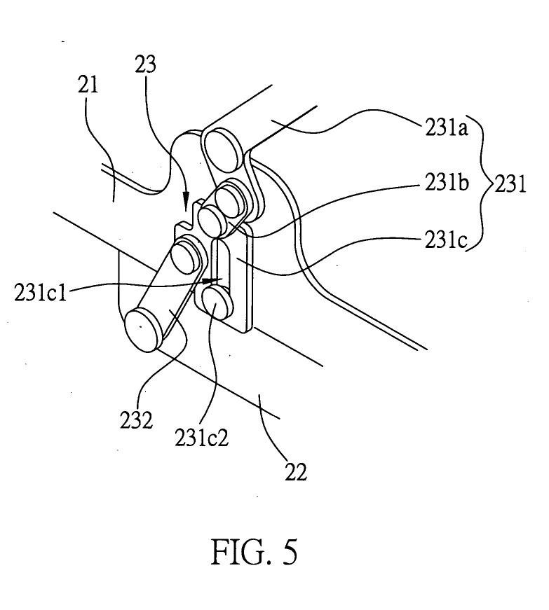

Referring to FIG. 5, the linkage arrangement 23 comprises a toggle mechanism 231 pivotally coupled with a lift lever 232 which is pivotally coupled with a sliding member 22. The toggle mechanism 231 comprises a lever 231a, a short lever 231b, and a swing lever 231c having a sliding slot 231c1, wherein a pivot 231c2 is mounted, allowing the swing lever 231c to move upwardly and downwardly using the pivot. Furthermore, the swing lever 231c is pivotally coupled with the lift lever 232 to drive the short lever 231b, the swing lever 231c and the lift lever 232 by pushing the lever 231a up and down so as to move the sliding member 22. The protruding column 31 of the heat sink 3 can then be fastened or unfastened through the movement of the sliding member thereby the heat sink 3 can be attached or released easily on the fixture 21.

In addition, the levers 231a of the linkage arrangement 23 mounted on two lateral side of the fixture 21 are coupled in one piece, in order to facilitate the movement of the lever 231a simultaneously.

The heat sink fastening structure proposed by the present invention therefore permits easy assembly and disassembly, furthermore, the pressure on the heat sink is evenly distributed, allowing the heat sink to be attached more evenly on a semiconductor package, compared to the prior art, so as to achieve optimal efficiency during operation.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A heat sink fastening structure for fixing a heat sink on a semiconductor package of a circuit board, comprising:
a fixture having a disposing space for disposing the heat sink therein;
two sliding members respectively slidingly mounted on two bottom-lateral sides of the fixture;
two linkage arrangements respectively mounted on two lateral sides of the fixture, and respectively pivotally coupled with the sliding members, so as to allow the linkage arrangements to be moved to drive the sliding members to fix the heat sink; and
two long groove holes mounted respectively on the two lateral sides of the fixture, wherein a locating pin is mounted in each of the two long groove holes, each locating pin being coupled to one of the sliding members and having an outer radius approximately equal to a width of the corresponding long groove hole but smaller than a length of the long groove hole, so as to allow the sliding members to slide underneath the fixture.

2. (canceled)

3. The heat sink fastening structure of claim 1, wherein, at least two opposing protruding columns each having a slot surrounding on an outside surface thereof are mounted on a bottom side of the heat sink.

4. The heat sink fastening structure of claim 3, wherein, a through hole is formed respectively on two lateral sides of the fixture and the sliding members, allowing each of the protruding columns of the heat sink to penetrate therein.

5. The heat sink fastening structure of claim 4, wherein, a long groove hole is formed respectively on each of the sliding members at a position opposing the through hole formed on the lateral sides of the fixture, allowing each of the protruding columns of the heat sink to penetrate the through hole formed on the lateral sides of the fixture and the long groove hole of the sliding members.

6. The heat sink fastening structure of claim 5, wherein, an elastic member is mounted diagonally on each of the sliding members, and a locking slot is formed on the elastic member at a position opposing to the long groove hole of each of the sliding members, so as to insert each of the protruding columns of the heat sink through the through hole of the fixture, the long groove hole of each of the sliding members and the locking slot of the elastic member.

7. The heat sink fastening structure of claim 6, wherein, the locking slot has a larger diameter at one end and a smaller diameter at the other end thereof.

8. The heat sink fastening structure of claim 7, wherein, with the diameter of one end of the locking slot being larger than that of the other end, when each of the linkage arrangements is pushed, each of the sliding members is moved from one end of the locking slot with a larger diameter to the other end of the locking slot with a smaller diameter so as to allow each of the protruding columns to be inserted into the locking slot via elastic force provided by the elastic member diagonally mounted thereon to drive the protruding column, thereby fastening the heat sink on the fixture.

9. The heat sink fastening structure of claim 1, wherein, each of the linkage arrangements comprises a toggle mechanism pivotally coupled with a lift lever that is pivotally coupled with each of the sliding members.

10. The heat sink fastening structure of claim 9, wherein, the toggle mechanism comprises a lever, a short lever, and a swing lever that is pivotally coupled with the lift lever.

11. The heat sink fastening structure of claim 10, wherein, the swing lever has a sliding slot, and a pivot is mounted in the sliding slot, allowing the swing lever to move upwardly and downwardly in relation to the pivot.

12. The heat sink fastening structure of claim 10, wherein, the lever of the linkage arrangements mounted on the two lateral sides of the fixture are integrally coupled to each other, so as to allow the lever to be moved simultaneously.

13. The heat sink fastening structure of claim 1, wherein, the semiconductor package is a central processor unit (CPU).

14. The heat sink fastening structure of claim 1, wherein, the fixture is placed on an outer surface of the semiconductor package and coupled to the circuit board.
